(19) United States
(12) Patent Application Publication
(10) Pub. No.: US 2009/0057573 A1
(43) Pub. Date: Mar. 5, 2009

(54) TECHNIQUES FOR TERMINAL INSULATION IN AN ION IMPLANTER

(75) Inventors: Russell John LOW, Rowley, MA (US); Piotr R. Lubicki, Peabody, MA (US); Jeffrey D. Lischer, Acton, MA (US); Steve Krause, Ipswich, MA (US); Eric Hermanson, Georgetown, MA (US); Joseph C. Olson, Beverly, MA (US); Kasegn D. Tekletsadik, Rexford, NY (US)

Correspondence Address: HUNTON & WILLIAMS LLP/VARIAN SEMICONDUCTOR,;EQUIPMENT ASSOCIATES, INC., INTELLECTUAL PROPERTY DEPARTMENT, 1900 K STREET, N.W., SUITE 1200, WASHINGTON, DC, 20006-1109, US

(73) Assignee: Varian Semiconductor Equipment Associates, Inc., Gloucester, MA (US)

(21) Appl. No.: 11/847,139

(22) Filed: Aug. 29, 2007

(51) Int. Cl. H01J 37/08

(52) U.S. Cl. 250/492.21

(57) ABSTRACT

Techniques for terminal insulation for an ion implanter are disclosed. In one particular exemplary embodiment, the techniques may be realized as an ion implanter comprising a terminal structure defining a terminal cavity. The ion implanter may also comprise a grounded enclosure defining a grounded cavity and the terminal structure may be at least partially disposed within the grounded cavity. The ion implanter may further comprise an intermediate terminal structure disposed proximate an exterior portion of the terminal structure and at least partially disposed within the grounded cavity.

### FIELD OF THE DISCLOSURE

The present disclosure relates generally to ion implantation and, more particularly, to techniques for terminal insulation in an ion implanter.

### BACKGROUND OF THE DISCLOSURE

Ion implantation is a standard technique for introducing impurities into semiconductor wafers. In an ion implantation process, a desired impurity material may be ionized in an ion source, ions from the ion source may be accelerated to form an ion beam of a prescribed energy, and the ion beam may be directed at a front surface of a work piece, such as a semiconductor wafer. The energetic ions in the ion beam may penetrate into a bulk portion of the semiconductor wafer and may be embedded into a crystalline lattice of the semiconductor material. The ion beam may be distributed over an area of the semiconductor wafer by beam movement, by wafer movement, or by a combination of beam and wafer movement.

An ion implanter may have a terminal structure. The terminal structure may sometimes be referred to as a “terminal” or “high voltage terminal” and may be fabricated of conductive material such as metal. The terminal structure may have varying geometries that define a cavity and the ion source may be at least partially disposed within the cavity. The terminal structure may be energized to a terminal voltage to assist with acceleration of ions from the ion source. The terminal structure, as well as other components and sub-systems of the ion implanter, are typically surrounded by a grounded enclosure. The grounded enclosure may thus protect personnel from high voltage dangers when the ion implanter is running.

Air has conventionally been used to insulate the terminal structure from the grounded enclosure. However, there may be a constraint on the distance of the air gap between the terminal structure and the grounded enclosure since the size of the grounded enclosure is limited in volume manufacturing of semiconductor wafers. Accordingly, most conventional ion implanters limit the voltage of the terminal structure to about 200 kV.

In view of the foregoing, it may be understood that there are significant problems and shortcomings associated with current terminal structure technologies.

### SUMMARY OF THE DISCLOSURE

Techniques for terminal insulation for an ion implanter are disclosed. In one particular exemplary embodiment, the techniques may be realized as an ion implanter comprising a terminal structure defining a terminal cavity. The ion implanter may also comprise a grounded enclosure defining a grounded cavity and the terminal structure may be at least partially disposed within the grounded cavity. The ion implanter may further comprise an intermediate terminal structure disposed proximate an exterior portion of the terminal structure and at least partially disposed within the grounded cavity.

In accordance with other aspects of this particular exemplary embodiment, the intermediate terminal structure may be configured to enclose the terminal structure.

In accordance with further aspects of this particular exemplary embodiment, the intermediate terminal structure may be configured to be disposed proximate a corner exterior portion of the terminal structure.

In accordance with additional aspects of this particular exemplary embodiment, the intermediate terminal structure may be configured to be energized to a first voltage and the terminal structure may be configured to be energized to a second voltage.

In accordance with yet another aspect of this particular exemplary embodiment, the first voltage may be configured to be approximately half of the second voltage.

In accordance with still another aspect of this particular exemplary embodiment, the intermediate terminal structure may be configured to have a radius matching at least a distance of an air gap space located between the terminal structure and the intermediate terminal structure or the intermediate terminal structure and the grounded enclosure.

In accordance with further aspects of this particular exemplary embodiment, the ion implanter may further comprise a bracket coupled to at least a portion of the terminal structure or the grounded enclosure.

In accordance with additional aspects of this particular exemplary embodiment, the bracket may be configured to support the intermediate terminal structure proximate the exterior portion of the terminal structure.

In accordance with another aspect of this particular exemplary embodiment, the intermediate terminal structure may be disposed about a roof of the grounded enclosure or a floor of the grounded enclosure.

In accordance with yet another aspect of this particular exemplary embodiment, the intermediate terminal structure may be fabricated from a dielectric material.

In accordance with still another aspect of this particular exemplary embodiment, the dielectric material may comprise at least one of polytetrafluoroethylene (PTFE), chlorinated polyvinyl chloride (CPVC), polyvinylidene difluoride (PVDF), ethylene chlorotrifluoroethylene (ECTFE).

In accordance with further aspects of this particular exemplary embodiment, the intermediate terminal structure may comprise a grading conductor disposed within a dielectric material.

In accordance with additional aspects of this particular exemplary embodiment, the dielectric material may comprise a tubular member defining an interior portion and the grading conductor may be disposed within the interior portion.

In accordance with another aspect of this particular exemplary embodiment, the intermediate terminal structure may be configured to be disposed at least on a floor portion of the grounded enclosure.

In accordance with yet another aspect of this particular exemplary embodiment, the intermediate terminal structure may be configured to be suspended proximate to the exterior portion of the terminal structure.

In accordance with still another aspect of this particular exemplary embodiment, the intermediate terminal structure may comprise at least one dielectric fin disposed proximate the exterior portion of the terminal structure.

In accordance with other aspects of this particular exemplary embodiment, the terminal structure may be disposed closer to a floor portion of the grounded enclosure than a roof portion of the grounded enclosure.

In accordance with further aspects of this particular exemplary embodiment, the intermediate terminal structure may be disposed on at least the floor portion, the roof portion or the sidewall portion of the grounded enclosure that may be closest to the terminal structure.

In another particular exemplary embodiment, the techniques may be realized as an ion implanter comprising a terminal structure defining a terminal cavity. The ion implanter may also comprise an intermediate terminal structure disposed proximate an exterior portion of the terminal structure and energized to a first voltage.

In accordance with other aspects of this particular exemplary embodiment, the terminal structure may be configured to be energized to a second voltage.

In accordance with further aspects of this particular exemplary embodiment, the first voltage may be approximately half of the second voltage.

The present disclosure will now be described in more detail with reference to exemplary embodiments thereof as shown in the accompanying drawings. While the present disclosure is described below with reference to exemplary embodiments, it should be understood that the present disclosure is not limited thereto. Those of ordinary skill in the art having access to the teachings herein will recognize additional implementations, modifications, and embodiments, as well as other fields of use, which are within the scope of the present disclosure as described herein, and with respect to which the present disclosure may be of significant utility.

### BRIEF DESCRIPTION OF THE DRAWINGS

In order to facilitate a fuller understanding of the present disclosure, reference is now made to the accompanying drawings, in which like elements are referenced with like numerals. These drawings should not be construed as limiting the present disclosure, but are intended to be exemplary only.

FIG. 1 is a top view of a block diagram of an ion implanter in accordance with an embodiment of the present disclosure.

FIG. 2 is a perspective view of the terminal structure of the ion implanter of FIG. 1 in accordance with an embodiment of the present disclosure.

FIG. 3 is a cross-sectional view of one embodiment of the intermediate terminal structure taken along the line A-A of FIG. 2 in accordance with an embodiment of the present disclosure.

FIG. 4 is a cross-sectional view of another embodiment of the intermediate terminal structure taken along the line A-A of FIG. 2 in accordance with an embodiment the present disclosure.

FIG. 5 is a cross-sectional view of another embodiment of the intermediate terminal structure taken along the line A-A of FIG. 2 in accordance with an embodiment of the present disclosure.

FIG. 6 is a cross-sectional view of another embodiment of the intermediate terminal structure taken alone the line A-A of FIG. 2 in accordance with an embodiment of the present disclosure.

FIG. 7 is a cross-sectional view of another embodiment of the intermediate terminal structure taken along the line A-A of FIG. 2 in accordance with an embodiment of the present disclosure.

FIG. 8 is a cross-sectional view of another embodiment of the intermediate terminal structure taken alone the line A-A of FIG. 2 in accordance with an embodiment of the present disclosure.

FIG. 9 is a cross-sectional view of another embodiment of the intermediate terminal structure taken alone the line A-A of FIG. 2 in accordance with an embodiment of the present disclosure.

FIG. 10 is a cross-sectional view of another embodiment of the intermediate terminal structure taken alone the line A-A of FIG. 2 in accordance with an embodiment of the present disclosure.

### DETAILED DESCRIPTION OF EXEMPLARY EMBODIMENTS

Embodiments of the present disclosure overcome inadequacies and shortcomings of existing terminal structures used in ion implanters by enclosing a terminal structure in an intermediate terminal structure and/or an intermediate dielectric barrier. The intermediate terminal structure may improve a breakdown voltage of the air by breaking up an air gap space between the terminal structure and a grounded enclosure into two air gap spaces. By breaking up the air gap space into smaller air gap spaces, the breakdown strength per inch of air may be increased, thereby preventing breakdowns and ensuring proper operation of an ion implanter. The breaking up of the air gap space may be accomplished by disposing one or more intermediate terminal structures between the terminal structure and the grounded enclosure. Also, the intermediate terminal structure may optimize a terminal geometry by matching the radii of the intermediate terminal structure and/or the terminal structure with that of the air gaps. Further, the intermediate terminal structure may reduce a voltage drop across the air gap. Moreover, the intermediate dielectric barrier may prevent a breakdown of air because an arc may not find a ground potential. It should be noted that, although the description hereinafter refers to a terminal structure in an ion implanter, the concepts disclosed herein may be used in other environments for increasing the breakdown strength of air about other conductive structures, Thus, the present disclosure is not limited to the embodiments described below.

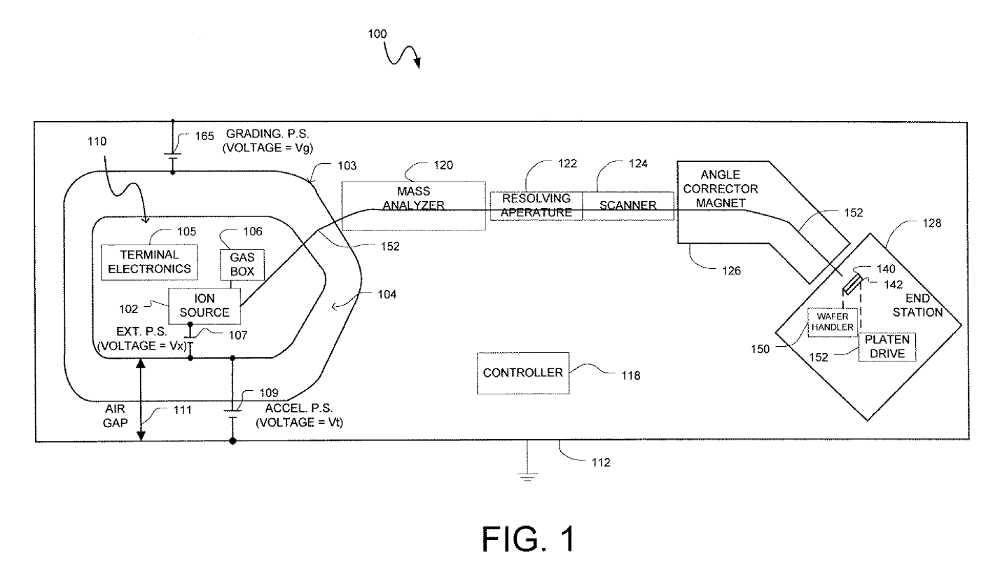

Referring to FIG. 1, there is shown an exemplary block diagram of an ion implanter 100 in accordance with an embodiment of the present disclosure. The ion implanter 100 may include a terminal structure 104 which may sometimes be referred to as a “terminal” or a “high voltage terminal.” The terminal structure 104 may be fabricated of a conductive material such as metal. The ion implanter 100 may also include one or more intermediate terminal structures (only one shown) 103 disposed proximate an exterior portion of the terminal structure 104 to break up an air gap space 111 between the terminal structure 104 and a grounded enclosure 112. The intermediate terminal structure 103 may be fabricated of a dielectric material and/or a conductor. The terminal structure 104 and the intermediate terminal structure 103 may be utilized in many different ion implanters known to those skilled in the art. Thus, the ion implanter 100 of FIG. 1 is but one embodiment of an ion implanter.

The ion implanter 100 may further include an ion source 102, a gas box 106, a mass analyzer 120, a resolving aperture 122, a scanner 124, an angle corrector magnet 126, an end station 128, and a controller 118. The ion source 102 is configured to provide an ion beam 152. The ion source 102 may generate ions and may include an ion chamber that accepts gas from the gas box 106. The gas box 106 may provide a source of gas to be ionized to the ion chamber. In addition, the gas box 106 may also contain other components such as power supplies. The power supplies may include arc, filament, and bias power supplies for running the ion source 102. The construction and operation of ion sources and the gas box are well known to those skilled in the art.

The mass analyzer 120 may include a resolving magnet that deflects ions so that ions of a desired species pass through the resolving aperture 122 and undesired species do not pass through the resolving aperture 122. Although showing about a 45 degree deflection for clarity of illustration, the mass analyzer 120 may deflect ions of the desired species by 90 degrees and deflect ions of undesired species by differing amounts due to their different masses and charge states. The scanner 124, positioned downstream from the resolving aperture 122, may include scanning electrodes for scanning the ion beam 152. The angle corrector magnet 126 deflects ions of the desired ion species to convert diverging ion beam paths to nearly collimated ion beam paths having substantial parallel ion trajectories. In one embodiment, the angle corrector magnet 126 may deflect ions of the desired ion species by 45 degrees.

The end station 128 may support one or more work pieces 140 (e.g., a wafer and/or other material to be implanted) in the path of the ion beam 152 such that ions of the desired species are implanted into each work piece 140. Each work piece 140 may be supported by a platen 142. The end station 128 may include other components and sub-systems known in the art such as a wafer handling system 150 to physically move the work piece 140 to and from the platen 142 from various holding areas. When the wafer handling system 150 moves the work piece 140 to the platen 142 from a holding area, the work piece 140 may be clamped to the platen 142 using known techniques, e.g., electrostatic wafer clamping where the wafer is clamped to the platen with electrostatic forces. The end station 128 may also include a platen drive system 152 as is known in the art to move the platen 142 in a desired way. The platen drive system 152 may be referred to as a mechanical scan system.

The controller 118 may receive input data from components of the ion implanter 100 and control the same. For clarity of illustration, input/output paths from the controller 118 to components of the ion implanter 130 are not illustrated in FIG. 1. The controller 118 can be or include a general-purpose computer or network of general-purpose computers that may be programmed to perform desired input/output functions. The controller 118 can also include other electronic circuitry or components, such as application specific integrated circuits, other hardwired or programmable electronic devices, discrete element circuits, etc. The controller 118 may also include user interface devices such as touch screens, user pointing devices, displays, printers, etc. to allow a user to input commands and/or data and/or to monitor the ion implantation system 100. The controller 118 may also include communication devices and data storage devices.

The ion beam 152 provided to a surface of the work piece 140 may be a scanned ion beam. Other ion implantation systems may provide a spot beam or a ribbon beam. The spot beam in one instance may have an approximately circular cross-section of a particular diameter depending on the characteristics of the spot beam. The ribbon beam may have a large width/height aspect ratio and may be at least as wide as the work piece 140. The scanner 124 would not be required for systems using a ribbon beam or a stationary spot beam. The ion beam 152 can be any type of charged particle beam, such as an energetic ion beam used to implant the work piece 140. The work piece 140 can take various physical shapes such as a common disk shape. The work piece 140 can be a semiconductor wafer fabricated from any type of semiconductor material such as silicon or any other material that is to be implanted using the ion beam 152.

The ion source 102, the gas box 106, and the terminal electronics 105 may be positioned within the cavity 110 defined by the terminal structure 104. The terminal electronics 105 may control operation of the components within the terminal structure 104 and may also be capable of communicating with the controller 118. An extraction power supply 107 may be coupled to the ion source 102. The extraction power supply 107 may provide a voltage level (Vx) to accelerate and extract ions from the ion source 102. In one embodiment, the extraction power supply may provide a voltage (Vx) in the range of 20 kV to 120 kV.

An additional acceleration power supply 109 may be coupled between the terminal structure 104 and the grounded enclosure 112 so as to bias the terminal structure 104 at a positive voltage (Vt) with respect to ground. In one embodiment, the acceleration power supply 109 may provide an additional voltage level (Vt) that may have a maximum voltage in the range of 200 kV to 1,000 kV, and may be approximately 400 kV in one embodiment. Accordingly, the terminal structure 104 may be energized, in some instances, to a high voltage between 200 kV and 1,000 kV. In other instances, the terminal structure 104 may not be energized at all or energized to nominal values only depending on the desired energy of the ion beam 152. Although only one acceleration power supply 109 is illustrated for clarity of illustration, two or more power supplies may be utilized to provide the desired maximum high voltage level (Vt).

Moreover, an additional grading power supply 165 may be coupled between the intermediate terminal structure 103 and the grounded enclosure 112 so as to bias the intermediate terminal structure 103 at a positive voltage (Vg) with respect to ground. In one embodiment, the grading power supply 165 may provide an additional voltage level (Vg) that may have a maximum voltage in the range of 100 kV to 1,000 kV, and may be at least 200 kV in one embodiment. Accordingly, the intermediate terminal structure 103 may be energized, in some instances, to a high voltage between 100 kV and 1,000 kV. In other instances, the intermediate terminal structure 103 may not be energized at all or energized to nominal values only depending on the desired energy of the ion beam 152. Although only one grading power supply 165 is illustrated for clarity of illustration, two or more power supplies may be utilized to provide the desired maximum high voltage level (Vg).

During operation of the ion implanter 100, the terminal structure 104 may be energized, in some instances, to at least 400 kV, e.g., 670 kV in one embodiment. The intermediate terminal structure 103 may be energized to at least 100 kV, e.g., 300 kV in one embodiment, and disposed proximate an exterior portion of the terminal structure 104. For example, the intermediate terminal structure 103 may be disposed half way between the terminal structure 104 and the grounded enclosure 112.

Furthermore, the intermediate terminal structure 103 may include a dielectric material having a rating of FM 4910 such as Teflon and/or CPVC. The intermediate terminal structure 103 may be made from a single continuous metal and/or dielectric material or segmented sections of metal and/or dielectric material. Also, the intermediate terminal structure 103 may enclose the terminal structure 104 therein and/or may be disposed at high electrical stress portions proximate the terminal structure 104. The intermediate terminal structure 103 may increase a withstand voltage of the terminal structure 104 by acting as a barrier to breakdown and reducing the path for potential arc to a ground potential, Also, the intermediate terminal structure 103 may increase a tracking distance between the terminal structure 104 and the grounded enclosure 112 which maximizes a linear distance between the terminal structure 104 and the grounded enclosure 112. Further, the intermediate terminal structure 103 may divide the air gap space 111 and reduce the geometric stress factor by better matching the intermediate terminal structure 103 radii to that of the air gap space 111. Furthermore, the intermediate terminal structure 103 may be energized to a grading voltage in order to modify a electric field stress. In other words, the intermediate terminal structure 103 may function as an electrical stress shield. Therefore, the terminal structure 104 may be energized to higher voltage levels, e.g., at least 600 kV as opposed to 200 kV, within the same reasonably sized grounded enclosure 112. Alternatively, for operation at the same lower terminal voltage of about 200 kV and less, the intermediate terminal structure 103 can enable the air gap space 111 to be reduced compared to air only insulation schemes.

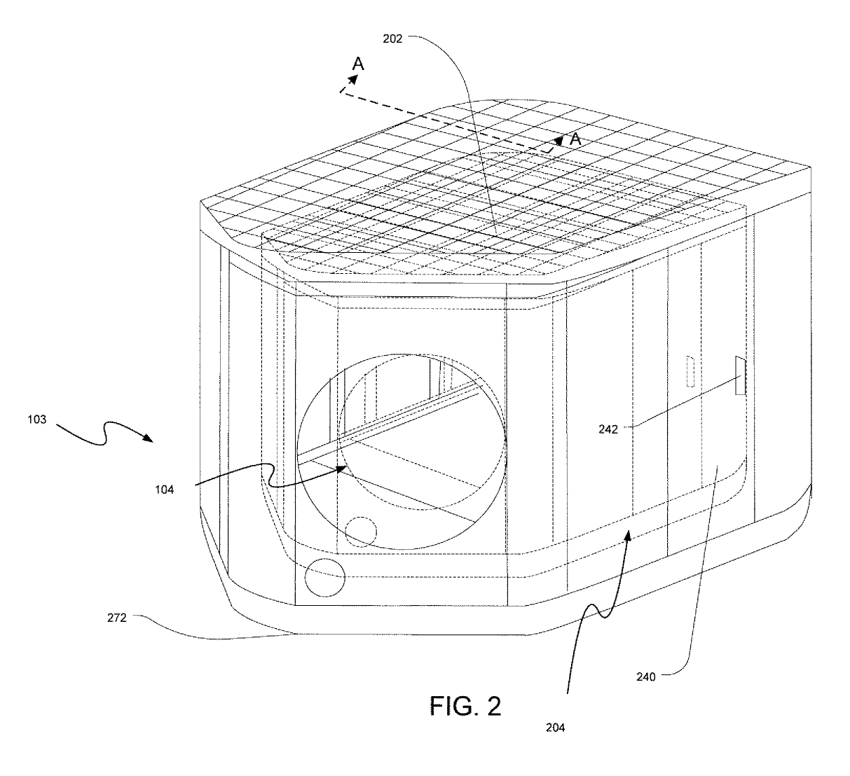

Referring to FIG. 2, there is shown an exemplary perspective view of the intermediate terminal structure 103 enclosing the terminal structure 104 (shown in phantom) in accordance with an embodiment of the present disclosure. The intermediate terminal structure 103 may include a base 272 and a top 202, each coupled to one or more upstanding sidewalls 204. One upstanding sidewall 204 may have a door 240 with a handle 242 to provide personnel access to the internal cavity of the intermediate terminal structure 103. The intermediate terminal structure 103 may have one upstanding sidewall manufactured of one solid material piece or any plurality of separate pieces. Although illustrated as a solid piece, the top 202 of the intermediate terminal structure 103 may also be fabricated of a plurality of spaced conductors forming a type of conductor mesh to allow air to flow through the openings of the mesh. The terminal structure 104 enclosed within the intermediate terminal structure 103 may be fabricated the same way with the same components as described above for intermediate terminal structure 103.

In general, the intermediate terminal structure 103 may enclose the terminal structure 104 and/or be disposed about portions of the exterior surface of the terminal structure 104 that have excess electrical stress. As shown in FIG. 2, the intermediate terminal structure 103 is disposed proximate the entire periphery of the terminal structure 104, thereby enclosing the terminal structure 104 within. Although the intermediate terminal structure 103 is disposed about the entirety periphery of the terminal structure 104, in alternative embodiments the intermediate terminal structure 103 may be disposed proximate exterior periphery portions of the terminal structure 104. These exterior periphery portions may include, but are not limited to, horizontal edges, vertical edges, corners, and openings or interfaces where the terminal structure 104 interfaces with external parts. Some external parts may include a generator, or a utility interface. In one example, a curve shaped intermediate terminal structure 103 may be positioned about a corner of the terminal structure 104.

A plurality of brackets 208 (not shown in FIG. 2) may be coupled to the terminal structure 104 and the intermediate terminal structure 103 to support the intermediate terminal structure 103 proximate an exterior periphery portion of the terminal structure 104. Also, the plurality of brackets 208 may be coupled to the grounded enclosure 112 and the intermediate terminal structure 103 to suspend the intermediate terminal structure 103 proximate an exterior periphery portion of the terminal structure 104. The number and position of the brackets 208 depends on the characteristics of the intermediate terminal structure 103, the geometry of the terminal structure 104, and the type of bracket. The brackets 208 may have a length to enable the intermediate terminal structure 103 to be positioned a desired distance from an exterior portion of the terminal structure 104. The desired distance may range from almost zero (nearly touching) to a maximum distance permitted by the surrounding grounded enclosure 112. In one embodiment, the desired distance is approximately 12-15 inches. The brackets 208 may be fabricated of either conductive of nonconductive material.

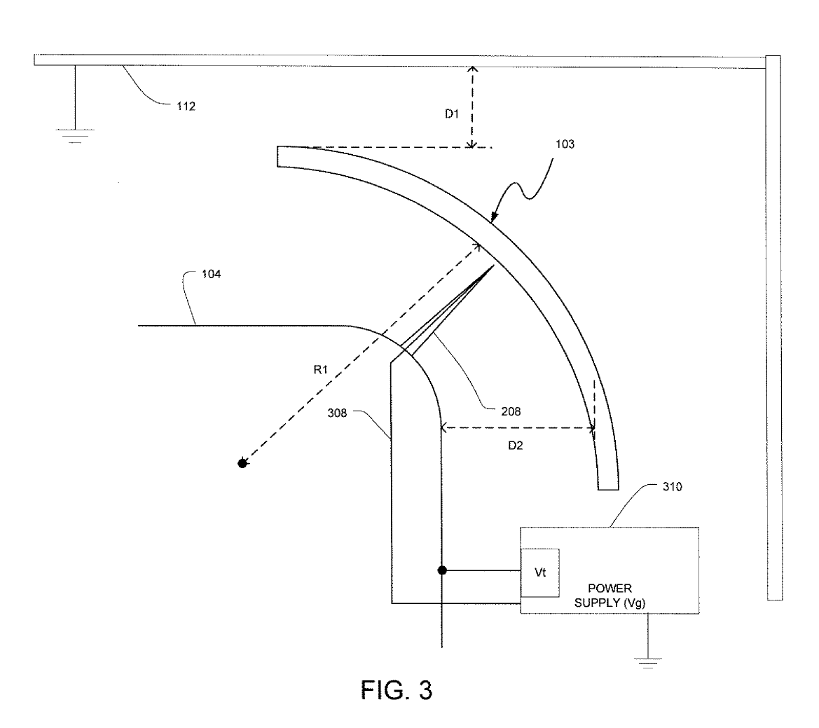

Referring to FIG. 3, there is shown an exemplary cross-sectional view of one embodiment of the intermediate terminal structure 103 taken along the line A-A of FIG. 2 in accordance with an embodiment of the present disclosure. The intermediate terminal structure 103 may be fabricated from a high voltage conductor having a solid cross-section. For example, the intermediate terminal structure 103 may be fabricated of the same high voltage conductive material as the terminal structure 104. In an alternative embodiment, the intermediate terminal structure 103 may be fabricated from a dielectric material having a rating of FM 4910. For example, the dielectric material of the intermediate terminal structure 103 may be a solid dielectric material. The solid dielectric material may include, but is not limited to, syntactic foam, plastic, Teflon, polytetrafluoroethylene (PTFE), chlorinated polyvinyl chloride (CPVC), polyvinylidene difluoride (PVDF), ethylene chlorotrifluoroethylene (ECTFE), or a polyimide (e.g., kapton). The syntactic foam may include hollow glass spheres and/or polymer pellets dispersed about a filling compound such as epoxy resin or silicone. In one embodiment, the intermediate terminal structure 103 may be fabricated from a plastic dielectric material enclosing the terminal structure 104. In other embodiments, the intermediate terminal structure 103 may be fabricated from a dielectric material encircling the corner exterior periphery portions of the terminal structure 104. Alternatively, the intermediate terminal structure 103 may have a chamber wall that defines an internal cavity where the terminal structure 104 may be disposed therein. The internal cavity of the intermediate terminal structure 103 may be filled with a liquid insulator or a gas insulator. The liquid insulator may include, but is not limited to, oil. The gas insulator may include, but is not limited to, carbon dioxide (CO₂), sulphur hexafluoride (SF₆), or pressurized air. Some gases may not need to be pressurized depending on their non-pressurized dielectric strength. Vacuum insulation and/or any combination to form a composite insulation may also be utilized. The intermediate terminal structure 103 can be fabricated as a single entity or composed and joined from segments of conductive and/or nonconductive materials.

A power supply 310 may energize the terminal structure 104 and the intermediate terminal structure 103. In one embodiment, the power supply 310 is configured to energize the intermediate terminal structure 103 to a first voltage, e.g., a grading voltage (Vg), and the terminal structure 104 to a second voltage, e.g., a terminal voltage (Vt). The grading voltage (Vg) may be approximately 200 kV and the terminal voltage may be at least 400 kV in one embodiment. The grading voltage and/or the terminal voltage may also be a DC voltage in one instance. A conductor 308 may electrically couple the power supply 310 to the intermediate terminal structure 103. The bracket 208 may be fabricated of a nonconductive material and the conductor 308 may be fed through an opening in the bracket 208. Therefore, the conductor 308 may enable the intermediate terminal structure 103 to be energized to a different voltage level than the terminal voltage (Vt).

Non-pressurized air may be present within the grounded enclosure 112 about the terminal structure 104 and the intermediate terminal structure 103. The non-pressurized air may have a dielectric strength of less than or equal to about 75 kV/inch under assumed conditions. This dielectric strength may change with relative humidity, altitude above sea level of the particular location of the ion implanter (i.e., air pressure), separation distance, and electrode surface finish. Temperature also impacts the breakdown strength of air. Essentially, the temperature and pressure (PV=nRT) changes show that what is actually changing is the air density. Air density impacts breakdown strength through pressure and temperature.

As a safety measure to account for such variations, a dielectric strength of less than or equal to about 45 kV/inch for air may be utilized as a design rule in one embodiment. In any event, it would be desirable to have the electric field stress at the exterior of the intermediate terminal structure 103 reduced to a value consistent with a selected design rule for air, even if the terminal structure 104 is energized to 600 to 1,000 kV. The air gap space ill may be divided into first air gap space and second air gap space by the intermediate terminal structure 103. The first air gap space may be disposed between the terminal structure 104 and the intermediate terminal structure 103 (e.g., distance D2) and the shortened air gap space may increase the breakdown strength voltage of the terminal structure 104. The shortened air gap may be able to withstand a greater breakdown voltage per inch than a larger air gap. In this way, the second air gap space between the intermediate terminal structure 103 and the grounded enclosure 112 (e.g., distance D1) may be adequate to insulate the terminal structure 104 without electrical breakdown, e.g., arcing.

The geometry of the intermediate terminal structure 103 may therefore be selected so that electric field stress at an exterior surface of the intermediate terminal structure 103 is less than a selected design rule for air. Also, electrical field stress may be reduced by eliminating geometric stress factors. For example, one method of eliminating geometric stress factors may be accomplished by matching radii of the intermediate terminal structure 103 and/or the terminal structure 104 to the distance of the air gap space 111. In an exemplary embodiment, the air gap space 111 may be approximately 30 inches and the radius of the terminal structure 104 may be approximately 15 inches. By providing an intermediate terminal structure 103 having a radius of approximately 15 inches at midway of the radius of the air gap space 111, the air gap space 111 may be divided into first and second air space spaces each having 15 inches in distance. Therefore, the radii of the terminal structure 104 and the intermediate terminal structure 103 may match the divided air gap space 111. In other embodiments, the radii of the terminal structure 104 and/or the intermediate terminal structure 103 may vary in accordance with the air gap space 111 and other design specifications. Furthermore, the location of the intermediate terminal structure 103 may be varied in accordance to the air gap space 111 and the air breakdown strength. In some embodiments, the radius (R1) of the intermediate terminal structure 103 may range approximately between 8 inches and 25 inches depending on the length of the air gap space 111 and the design rule selected for electrical stress in air. The bracket 208 has a length to enable the intermediate terminal structure 103 to be positioned a distance (D2) of approximately between 8 inches and 25 inches from the terminal structure 104.

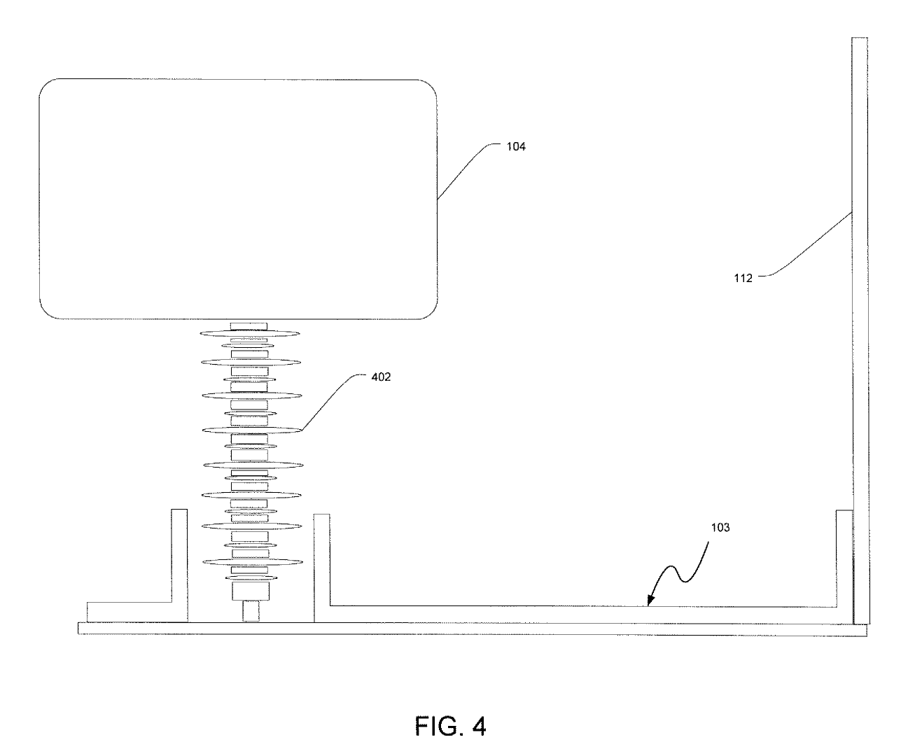

Referring to FIG. 4, there is shown an exemplary cross-sectional view of one embodiment of the intermediate terminal structure 103 taken along the line A-A of FIG. 2 in accordance with another embodiment of the present disclosure. The terminal structure 104 may be supported by a supporting member 402 above a floor portion of the grounded disclosure 112. The intermediate terminal structure 103 may be disposed proximate to a floor portion of the terminal structure 104. The intermediate terminal structure 103 may be made from a dielectric material disposed on a floor portion of the grounded enclosure 112. Indeed, a surface tracking distance may be increased by disposing a dielectric intermediate terminal structure 103 on a floor portion of the grounded enclosure 112. The intermediate terminal structure 103 may be designed as a barrier separating the terminal structure 104 from the grounded enclosure 112 and reducing a path of a potential arc to the grounded enclosure 112. The intermediate terminal structure 103 may cover the entire floor or a portion of the floor of the grounded enclosure 112. In other embodiments, multiple layers of intermediate terminal structure 103 may be disposed proximate to the floor portion of the terminal structure 104 in order to prevent an arc from reaching the grounded potential.

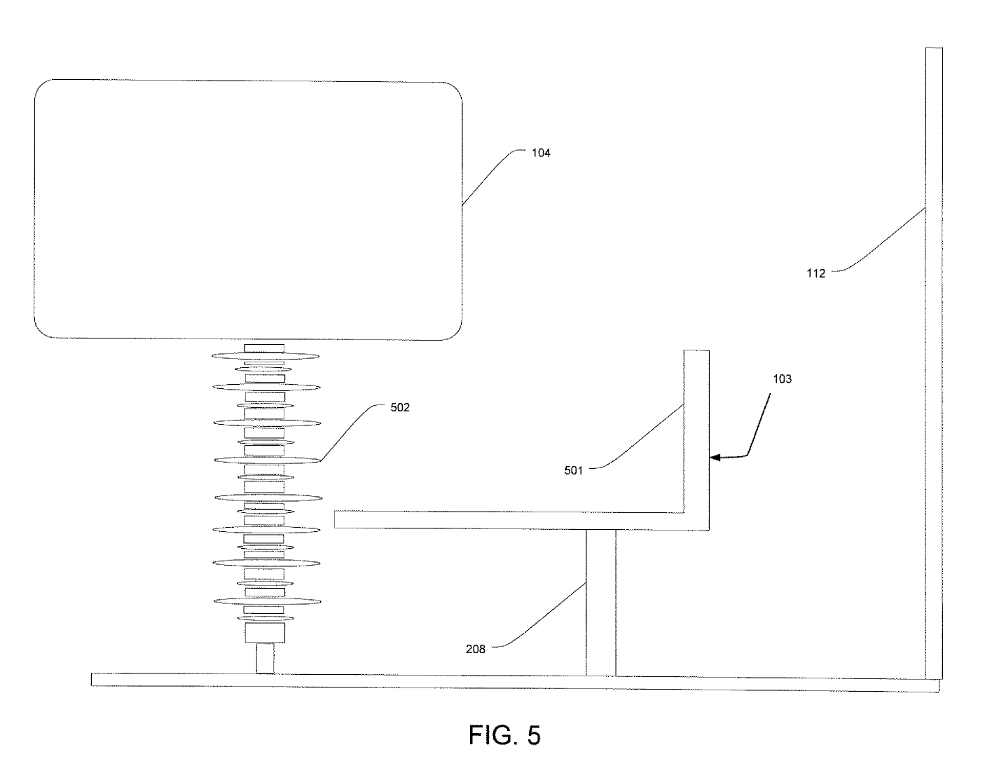

Referring to FIG. 5, there is shown an exemplary cross-sectional view of one embodiment of the intermediate terminal structure 103 taken along the line A-A of FIG. 2 in accordance with another embodiment of the present disclosure. The terminal structure 104 may be supported by a supporting member 502 above a floor portion of the grounded disclosure 112. A plurality of brackets 208 may be coupled to the grounded enclosure 112 and the intermediate terminal structure 103 to suspend the intermediate terminal structure 103 proximate an exterior periphery portion of the terminal structure 104. Also, the intermediate terminal structure 103 may be suspended to enclose the terminal structure 104 therein. The intermediate terminal structure 103 may include a dielectric fin 501 to prevent breakdowns by increasing a tracking distance and reducing a path for a potential arc to the grounded enclosure 112. Also, the intermediate terminal structure 103 may be suspended proximate to a high electrical stress exterior periphery portion of the terminal structure 104. The suspended intermediate terminal structure 103 may be disposed between the terminal structure 104 and the grounded enclosure 112 in order prevent breakdowns by increasing a tracking distance and reducing a path for a potential arc to the grounded enclosure 112. Also, the location of the suspended intermediate terminal structure 103 may be adjusted in accordance to the air gap space 111 and the presence of electrical stress. The bracket 208 and the intermediate terminal structure 103 may be fabricated from the same dielectric material or from disparate dielectric materials. In other embodiments, the intermediate terminal structure 103 may have multiple layers disposed proximate to the exterior periphery portion of the terminal structure 104 in order to prevent an arc from reaching the grounded potential.

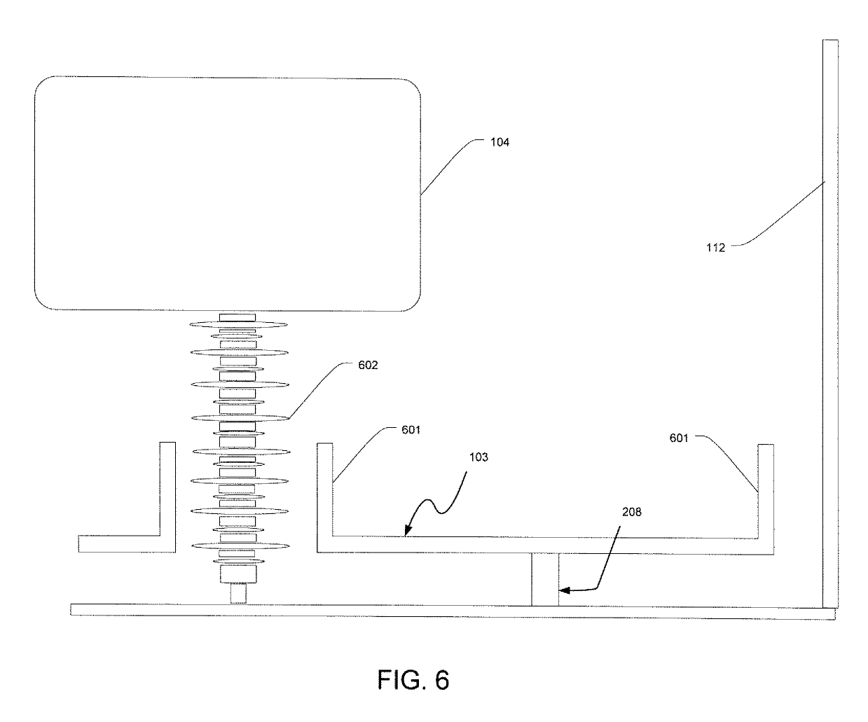

Referring to FIG. 6, there is shown an exemplary cross-sectional view of one embodiment of the intermediate terminal structure 103 taken along the line A-A of FIG. 2 in accordance with another embodiment of the present disclosure. The terminal structure 104 may be supported by a supporting member 602 above a floor portion of the grounded disclosure 112. A plurality of brackets 208 may be coupled to the grounded enclosure 112 and the intermediate terminal structure 103 to suspend the intermediate terminal structure 103 proximate an exterior portion of the terminal structure 104. Also, the intermediate terminal structure 103 may be suspended proximate to a high electrical stress exterior portion of the terminal structure 104. The intermediate terminal structure 103 may include two dielectric fins 601 in order to modify a tangential electric field and a normal electric field. The movement of a charged particle over the surface of the intermediate terminal structure 103 may be inhibited by changing the tangential electric field and the normal electric field therefore a surface flashover may be inhibited. The suspended intermediate terminal structure 103 may be disposed between the terminal structure 104 and the grounded enclosure 112 in order to modify the tangential electric field and normal electric field distribution surrounding the terminal structure 104. Also, the location of the suspended intermediate terminal structure 103 may be adjusted in accordance to the air gap space 111 and the presence of electrical stress. The bracket 208 and the intermediate terminal structure 103 may be fabricated from the same dielectric material or from disparate dielectric materials. In other embodiments, the intermediate terminal structure 103 may have multiple layers disposed proximate to the exterior periphery portion of the terminal structure 104 in order to prevent an arc from reaching the grounded potential.

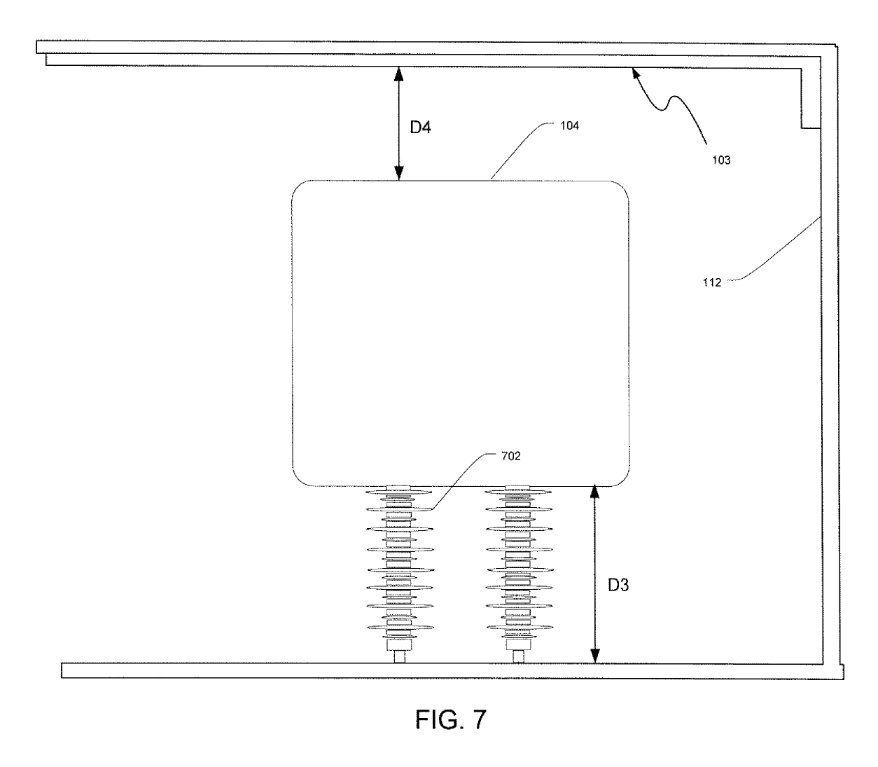

Referring to FIG. 7, there is shown an exemplary cross-sectional view of one embodiment of the intermediate terminal structure 103 taken along the line A-A of FIG. 2 in accordance with another embodiment of the present disclosure. The terminal structure 104 may be supported by a supporting member 702 above a floor portion of the grounded disclosure 112. The terminal structure 104 may be disposed at a distance (D3) from a floor of the grounded enclosure 112. For example, the distance (D3) may be greater than 30 inches. Also, the terminal structure 104 may be disposed at a distance (D4) from a roof of the grounded enclosure 112. For example, the distance (D4) may be less than 30 inches. As shown in FIG. 7, the terminal structure 104 is disposed closer to the roof than to the floor of the grounded enclosure 112. Therefore, the roof of the grounded enclosure 112 may experience higher electrical field stress and higher air breakdowns due to the closer proximity to the terminal structure 104. Therefore, the intermediate terminal structure 103 may be disposed on the roof of the grounded enclosure 112. The intermediate terminal structure 103 may be fabricated from nonconductive material, for example, a dielectric material. In an alternative embodiment, the intermediate terminal structure 103 may include a conductor disposed on the dielectric material and may be energized to a grading voltage.

Furthermore, the terminal structure 104 may be disposed closer to the floor than the roof of the grounded enclosure 112 or closer to one or more side walls than other side walls of the grounded enclosure 112. Thus, the intermediate terminal structure 103 may be disposed on the floor or the side walls of the grounded enclosure 112 in order to reduce electrical field stress due to the closer proximity to the terminal structure 104 and reduce the path for a potential arc to the grounded enclosure 112. In other embodiments, the intermediate terminal structure 103 may have multiple layers disposed on an interior portion of the grounded enclosure 112 in order to reduce electrical field stress and increase surface tracking distance.

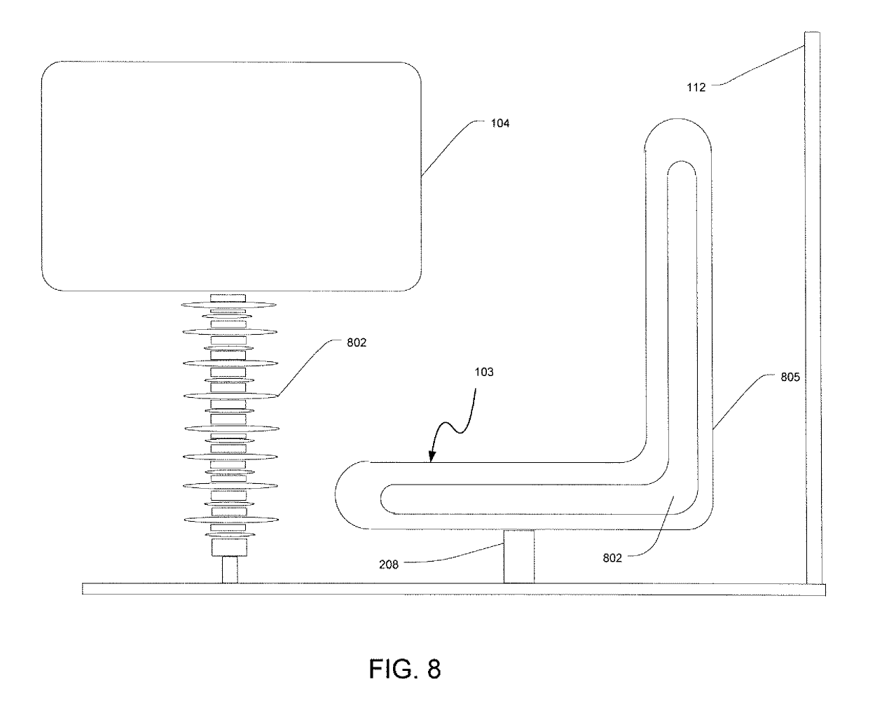

Referring to FIG. 8, there is shown an exemplary cross-sectional view of one embodiment of the intermediate terminal structure 103 taken along the line A-A of FIG. 2 in accordance with another embodiment of the present disclosure. The terminal structure 104 may be supported by a supporting member 802 above a floor portion of the grounded disclosure 112. The intermediate terminal structure 103 includes a dielectric material 805 disposed about a conductor 802. The intermediate terminal structure 103 may enclose the terminal structure 104 therein. Also, the intermediate terminal structure 103 may be disposed proximate an exterior portion of the terminal structure 104. In one embodiment, the dielectric material 805 may be a solid dielectric. Alternatively, the dielectric material 805 may have a chamber wall that defines an internal cavity and the internal cavity may be filled with a liquid insulator or a gas insulator. The liquid insulator may include, but is not limited to, oil. The gas insulator may include, but is not limited to, carbon dioxide (CO₂), sulphur hexafluoride (SF₆), or pressurized air. Some gases may not need to be pressurized depending on their non-pressurized dielectric strength. Vacuum insulation and/or any combination to form a composite insulation may also be utilized. The conductor 802 may be a high voltage conductor having a solid cross-section.

A power supply 310 (shown in FIG. 3), may energize the terminal structure 104 and the intermediate terminal structure 103. In one embodiment, the power supply 310 may be configured to energize the intermediate terminal structure 103 to a first voltage, e.g., a grading voltage (Vg) and the terminal structure 104 to a second voltage, e.g., a terminal voltage (Vt). The conductor 308 (shown in FIG. 3), may electrically couple the power supply 310 to the intermediate terminal structure 103. The bracket 208 may be fabricated of a nonconductive material and the conductor 308 may be fed through an opening in the bracket 208. The bracket 208 may have a length to enable the intermediate terminal structure 103 to be positioned a desired distance from an exterior portion of the terminal structure 104.

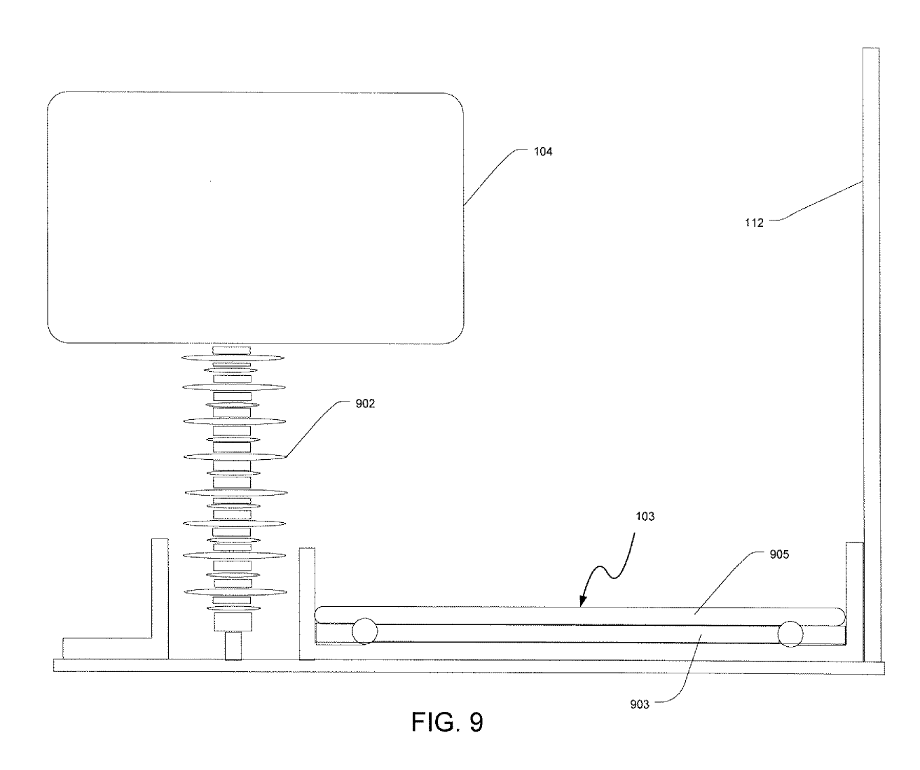

Referring to FIG. 9, there is shown an exemplary cross-sectional view of one embodiment of the intermediate terminal structure 103 taken along the line A-A of FIG. 2 in accordance with another embodiment of the present disclosure. The terminal structure 104 may be supported by a supporting member 902 above a floor portion of the grounded disclosure 112. The intermediate terminal structure 103 may be disposed proximate to a floor portion of the terminal structure 104. The intermediate terminal structure 103 may be disposed on a floor of the grounded enclosure 112. The intermediate terminal structure 103 may be designed as a barrier separating the terminal structure 104 from the grounded enclosure 112. The intermediate terminal structure 103 may cover the entire floor of the grounded enclosure 112 or a portion of the floor of the grounded enclosure 112. In other embodiments, the intermediate terminal structure 103 may have multiple layers disposed proximate to the base portion of the terminal structure 104 in order to prevent an arc from reaching the grounded potential.

The intermediate terminal structure 103 includes an dielectric material 905 disposed about a conductor 903. In one embodiment, the dielectric material 905 may be a solid dielectric. Alternatively, the dielectric material 905 may have a chamber wall that defines an internal cavity and the internal cavity may be filled with a liquid insulator or a gas insulator. The liquid insulator may include, but is not limited to, oil. The gas insulator may include, but is not limited to, carbon dioxide (CO₂), sulphur hexafluoride (SF₆), or pressurized air. Some gases may not need to be pressurized depending on their non-pressurized dielectric strength. Vacuum insulation and/or any combination to form a composite insulation may also be utilized. The conductor 903 may be a high voltage conductor having a solid cross-section.

A power supply 310 (shown in FIG. 3), may energize the terminal structure 104 and the intermediate terminal structure 103. In one embodiment, the power supply 310 is configured to energize the intermediate terminal structure 103 to a first voltage, e.g., a grading voltage (Vg) and the terminal structure 104 to a second voltage, e.g., a terminal voltage (Vt). By energizing the intermediate terminal structure 103 to a grading voltage, the voltage difference between the terminal structure 104 and the intermediate terminal structure 103 may be reduced. The reduction in the voltage difference may reduce the electric field stress between the terminal structure 104 and the intermediate terminal structure 103 and thus increase a voltage to be withstood by the terminal structure 104. Any remaining voltage between the intermediate terminal structure 112 and the ground enclosure 112 may be withstood by the dielectric material.

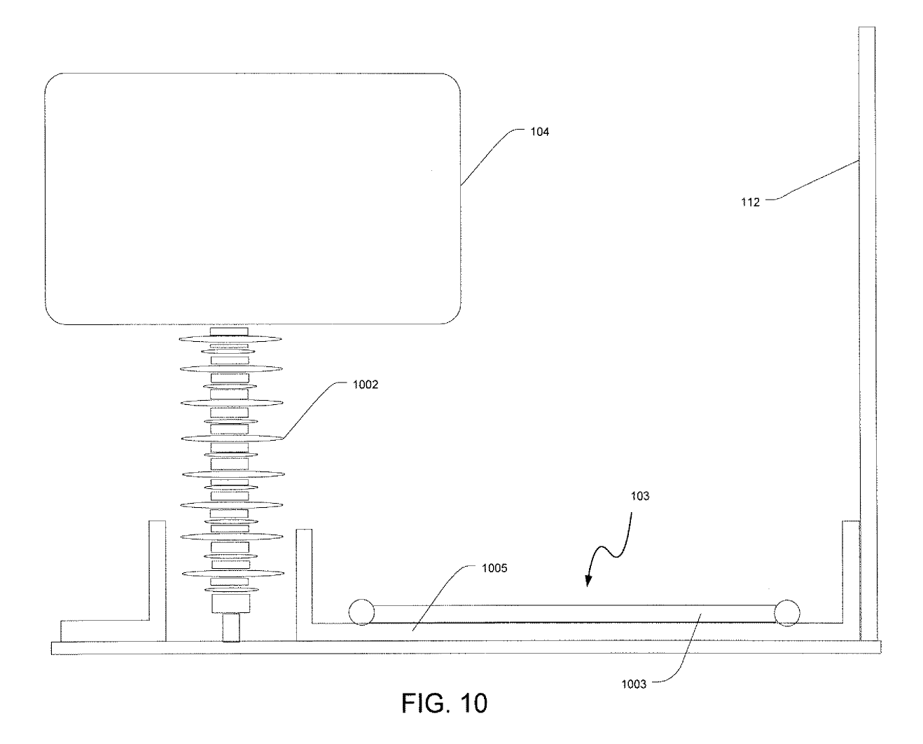

Referring to FIG. 10, there is shown an exemplary cross-sectional view of one embodiment of the intermediate terminal structure 103 taken along the line A-A of FIG. 2 in accordance with another embodiment of the present disclosure. The terminal structure 104 may be supported by a supporting member 1002 above a floor portion of the grounded disclosure 112. The intermediate terminal structure 103 may be disposed proximate to a floor portion of the terminal structure 104. The intermediate terminal structure 103 may be disposed on a floor of the grounded enclosure 112. Also, the intermediate terminal structure 103 may be disposed on a roof portion and/or a sidewall portion of the grounded enclosure 112. The intermediate terminal structure 103 may be designed as a barrier separating the terminal structure 104 from the grounded enclosure 112. The intermediate terminal structure 103 may cover the entire floor of the grounded enclosure 112 or a portion of the floor of the grounded enclosure 112. In other embodiments, the intermediate terminal structure 103 may have multiple layers disposed proximate to the base portion of the terminal structure 104 in order to prevent an arc from reaching the grounded potential.

The intermediate terminal structure 103 may include an dielectric material 1005 disposed about a conductor 1003. In one embodiment, the dielectric material 1005 may be a solid dielectric disposed between the conductor 1003 and the grounded enclosure 112. Alternatively, the dielectric material 1005 may have a chamber wall that defines an internal cavity and the internal cavity may be filled with a liquid insulator or a gas insulator. The liquid insulator may include, but is not limited to, oil. The gas insulator may include, but is not limited to, carbon dioxide (CO₂), sulphur hexafluoride (SF₆), or pressurized air. Some gases may not need to be pressurized depending on their non-pressurized dielectric strength. Vacuum insulation and/or any combination to form a composite insulation may also be utilized. The conductor 1003 may be a high voltage conductor having a solid cross-section.

A power supply 310 (shown in FIG. 3), may energize the terminal structure 104 and the intermediate terminal structure 103. In one embodiment, the power supply 310 is configured to energize the intermediate terminal structure 103 to a first voltage, e.g., a grading voltage (Vg) and the terminal structure 104 to a second voltage, e.g., a terminal voltage (Vt). By energizing the intermediate terminal structure 103 to a grading voltage, the voltage difference between the terminal structure 104 and the grounded enclosure 112 may be reduced. Also, the reduction in the voltage difference may reduce the electric field stress and thus increase a voltage to be withstood by the terminal structure 104. An electrical stress may be created between the conductor 1003 and the grounded enclosure 112. Hence, the dielectric material 1005 may be disposed between the conductor 1003 and the grounded enclosure 112 in order to inhibit electrical breakdown between the conductor 1003 and the grounded enclosure 112. The dielectric material 1005 may include two dielectric fins in order to increase the surface tracking distance to the grounded enclosure 112.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

1. An ion implanter, comprising:
a terminal structure defining a terminal cavity,
a grounded enclosure defining a grounded cavity, the terminal structure at least partially disposed within the grounded cavity;
an intermediate terminal structure disposed proximate an exterior portion of the terminal structure and at least partially disposed within the grounded cavity.

2. The ion implanter according to claim 1, wherein the intermediate terminal structure is configured to enclose the terminal structure.

3. The ion implanter according to claim 1, wherein the intermediate terminal structure is configured to be disposed proximate a corner exterior portion of the terminal structure.

4. The ion implanter according to claim 1, wherein the intermediate terminal structure is configured to be energized to a first voltage and the terminal structure is configured to be energized to a second voltage.

5. The ion implanter according to claim 4, wherein the first voltage is configured to be approximately half of the second voltage.

6. The ion implanter according to claim 1, wherein the intermediate terminal structure is configured to have a radius matching at least a distance of an air gap space located between the terminal structure and the intermediate terminal structure or the intermediate terminal structure and the grounded enclosure.

7. The ion implanter according to claim 1, further comprising a bracket coupled to at least a portion of the terminal structure or the grounded enclosure.

8. The ion implanter according to claim 7, wherein the bracket is configured to support the intermediate terminal structure proximate the exterior portion of the terminal structure.

9. The ion implanter according to claim 1, wherein the intermediate terminal structure is disposed about a roof of the grounded enclosure or a floor of the grounded enclosure.

10. The ion implanter according to claim 8, wherein the intermediate terminal structure is fabricated from a dielectric material.

11. The ion implanter according to claim 9, wherein the dielectric material comprises at least one of polytetrafluoroethylene (PTFE), chlorinated polyvinyl chloride (CPVC), polyvinylidene difluoride (PVDF), ethylene chlorotrifluoroethylene (ECTFE).

12. The ion implanter according to claim 1, wherein the intermediate terminal structure comprises a grading conductor in conjunction with a dielectric material.

13. The ion implanter according to claim 12, wherein the dielectric material comprises a tubular member defining an interior portion, the grading conductor disposed within the interior portion.

14. The ion implanter according to claim 12, wherein the intermediate terminal structure is configured to be disposed at least on a floor portion of the grounded enclosure.

15. The ion implanter according to claim 12, wherein the intermediate terminal structure is configured to be suspended proximate to the exterior portion of the terminal structure.

16. The ion implanter according to claim i, wherein the intermediate terminal structure comprises at least one dielectric fin disposed proximate the exterior portion of the terminal structure.

17. The ion implanter according to claim 1, wherein the terminal structure is disposed closer to a roof portion of the grounded enclosure than a floor portion of the grounded enclosure.

18. The ion implanter according to claim 17, wherein the intermediate terminal structure is disposed on at least the floor portion, the roof portion or the sidewall portion of the grounded enclosure that is closest to the terminal structure.

19. The ion implanter according to claim 1, wherein the intermediate terminal structure further comprises one or more layers disposed proximate an exterior portion of the terminal structure

20. An ion implanter, comprising:
a terminal structure defining a terminal cavity,
an intermediate terminal structure disposed proximate an exterior portion of the terminal structure and energized to a first voltage.

21. The method according to claim 20, wherein the terminal structure is configured to be energized to a second voltage.

22. The ion implanter according to claim 21, wherein the first voltage is approximately half of the second voltage.
